(19) United States
(12) Patent Application Publication
(10) Pub. No.: US 2002/0090846 A1
(43) Pub. Date: Jul. 11, 2002

(54) Interface connector for a hardware device

(76) Inventor: Pierre Abboud, Encino, CA (US)

Correspondence Address: Michael S. Doll, Suite 1550, 200 Oceangate, Long Beach, CA, 90802, US

(21) Appl. No.: 09/757,244

(22) Filed: Jan. 8, 2001

(51) Int. Cl. H05K 1/00

(52) U.S. Cl. 439/76.1

(57) ABSTRACT

An interface connector including a circuit board overlay having an interface connector section including opposing sides with electrical contact areas for receipt of one end of a pair of complementary interface connectors projecting in parallel planes and being in electrical communication with one another such that like configured interface connectors may stack together in a substantially aligned arrangement with at least one connector being free to connect to a digital processing or data generating unit. A third connector is provided on one the sides for connecting to a hardware unit to the interface connector and is in electrical communication with both of said interface connectors.

### BACKGROUND OF THE INVENTION

1. Field of the Invention

The invention relates generally to interface connectors and more specifically, to interface connectors for use in connection with electrical components.

2. Description of the Prior Art

External peripherals and internal hardware for the digital processing and data generating environments are often used to extend the capabilities of a primary processing device such as a desktop or laptop computer, a network environment, or a digital data generator such as a digital camcorder. Examples of hardware devices commonly used to expand the capabilities of these primary digital processing or generating systems include drives of the CD-ROM, CD-R, CD-RW, Hard, Floppy, DVD, Tape, WORM, Jaz, and Zip variety as well as MP3 or audio file players.

While such devices expand the capabilities of the primary device, the advancement of multimedia digital data capabilities and the file size required to store such data for repeated use over long periods of time has placed a premium on storage space. Thus, technological developments in the peripheral and internal hardware field tend to focus on providing more storage in a smaller package with faster access times. Typically this is accomplished using a hard disk drive which may be an internal or external device in relation to the primary device. The computer sector continues to develop hard disk drives with larger capacity in smaller casings to address these data storage needs. While this increase in capacity and reduction in size of the hard disk drive technology would seemingly reduce the number of drive units required for each system, it is apparent that the storing of digital data still requires a considerable amount of capacity such that multiple drive units are often required for a single system. In addition, new multimedia devices with enhanced capabilities continue to be developed and each new development appears capable of using more drive space to take full advantage of the enhancements and store the data effectively. Thus, it remains essential to accommodate the incorporation of multiple hardware devices in a single processing environment or in more complex network systems. Due to the variety of primary devices, it also remains advantageous to provide hardware devices with the versatility to be incorporated into a variety of working environments.

To accommodate the incorporation of multiple hardware devices, two primary standards have become apparent in the digital data processing and generating fields. The first is an internal configuration within a primary device casing. The hardware devices are typically rack mounted within the computer casing and are connected via an interface cable running from a connector in a rear interface panel in the hardware device to a slot in the main processing board of the computer. The rack mountings may be dimensioned to accommodate a variety of drive sizes or may be standardized. Conventional computer casings accommodate from one to three drives within a single computer casing and are typically limited by the main processing board and size of the computer casing. Laptops typically accommodate only a pair of drives. Another internal configuration is the tower which is merely a larger computer casing with additional rack mounts to accommodate a larger number of hardware devices. The hardware devices are typically stored in a vertical alignment and separated by the individual rack mounts with their respective rear interface connector panels aligned but spaced apart.

The second configuration often encountered is the external peripheral. The popularity of external hardware peripheral equipment arises in part from the convenience of merely plugging the peripheral into a primary device such as a computer via an interface cable thereby saving the user from opening up the casing of the computer. The external peripherals typically include a rear interface panel with an outwardly projecting connector. To accommodate multiple external hardware devices, the primary devices include a number of separate ports for each hardware device or a main hub designed to act as a central connection port for a number of hardware devices. This configuration may overcome the restrictions created by the internal size and number of internal sockets of the main processor housing but also increases the need for individual cable connectors to connect each hardware unit to the primary device.

While both of these configurations address the incorporation of multiple hardware devices for use in conjunction with a primary device, it is apparent that there is a lag in the interface technology. For instance, each hardware device must be individually connected to either an internal socket or an external port on the primary device or connected to a central hub connected to the primary device. To accomplish this, an interface cable is commonly used. Each hardware peripheral typically includes a rear interface panel with a rearwardly projecting connector typically constructed to interface with a specific interface connector such as a Small Computer Serial Interface (SCSI), parallel, or Universal Serial Bus (USB) connector. The hub or port on the primary device includes a connector for receiving the opposing end of the interface cable. This requires the use of one cable for each hardware device. While this configuration may be acceptable for a single device, the use of multiple devices results in a clutter of unnecessary cabling. In other words, if multiple peripherals are incorporated in a stacked or unstacked configuration, a series of connector cables is required to supply signals and power to each of the peripherals and to connect the peripherals to a primary device. In some instances, a single ribbon cable having multiple connectors may be used. Due to the rearward projection of the connector on the interface panel of the hardware devices, a length of cable is provided when connecting two such devices together. Thus, the use of multiple hardware devices in a stacked or unstacked configuration often results in a tangle of twisted cables and takes up more space than necessary. In addition, such cables also add resistance to the lines which reduces the overall effectivity of the signal flow.

What is needed and heretofore unavailable is an interface connector reducing the requirement for interface cabling in a multiple hardware device environment with the versatility to be used in a variety of digital processing systems.

### SUMMARY OF THE INVENTION

In accordance with a preferred embodiment of the present invention, an interface connector including a circuit board overlay with opposing first and second sides having electrically conductive contact areas including complementary interface connectors on opposite sides of the interface connector and in electrical communication with their respective contact areas. Such interface connectors are aligned in a parallel relationship and face opposite directions such that they may be connected in series with other interface connectors of a like configuration without requiring an interface cable. Multiple interface connectors may thus be stacked in an aligned arrangement.

Another feature of the present invention is the incorporation of alternative connectors for connecting to a hardware device or connecting the interface connector to a primary device.

Yet another feature of the present invention is the incorporation of connectors that are compatible with IEEE 1394 standards.

A method for stacking multiple hardware units without using interface cabling is also described herein.

Other features and advantages of the present invention will become more apparent from the following detailed description of the invention, when taken in conjunction with the accompanying exemplary drawings.

### BRIEF DESCRIPTION OF THE DRAWINGS

FIG. 1 is a forward perspective view of an interface connector device embodying the present invention with representative componentry;

FIG. 2 is a reverse side view, in reduced scale, of the device shown in FIG. 1 depicting a detachable hardware unit;

FIG. 3 is a side view of two like configured devices as shown in FIG. 1, in enlarged scale, illustrating a multiple stacking configuration with an exemplary housing indicated by phantom lines;

FIG. 4 is a top plan view of the hardware device, in enlarged scale, detached from the circuit board overlay of the embodiment illustrated in FIG. 1;

FIG. 5 is a top view, in reduced scale, of the interface connector device as illustrated in FIG. 1 depicting the surface features of the circuit board without the main connectors;

FIG. 6 is a bottom view, in reduced scale, of the interface connector device as iilustrated in FIG. 1 depicting the surface features of the circuit board without the main connectors;

FIG. 7A is top view of a female connector, in enlarged scale, for attachment to the circuit board overlay as illustrated in FIG. 5;

FIG. 7B is a bottom view of the connector depicted in FIG. 7A;

FIG. 8A is a top view of a male connector, in enlarged scale, for attachment to the circuit board overlay illustrated in FIGS. 5 and 6;

FIG. 8B is a top view of the connector depicted in FIG. 8A;

FIG. 9 is left hand end view, in enlarged scale, of the interface connector depicted in FIG. 1;

FIG. 10 is a bottom view, in enlarged scale, of the interface connector depicted in FIG. 1 with the hardware unit indicated in phantom lines;

FIG. 11 is a superimposed top view, in enlarged scale, of the aligned surface mount contact areas illustrated in FIGS. 5 and 6;

FIG. 12A is view of the narrow flat end of an alternative female connector;

FIG. 12B is a side view of the female connector illustrated in FIG. 12A;

FIG. 12C is view of the faceted end of the female connector illustrated in FIG. 12A;

FIG. 12D is pin configuration pattern for the connector illustrated in FIGS. 12A-12C;

FIG. 13A is an rear end view of the aligned connectors, in enlarged scale as illustrated in FIG. 9 including a sectional view of the circuit board; and

FIG. 13B is a side view of the connector illustrated in FIG. 13A.

Numerous advantages and aspects of the invention will be apparent to those skilled in the art upon consideration of the following detailed description which generally provides illustrations of the invention in its presently preferred embodiments.

### DETAILED DESCRIPTION OF THE PREFERRED EMBODIMENTS

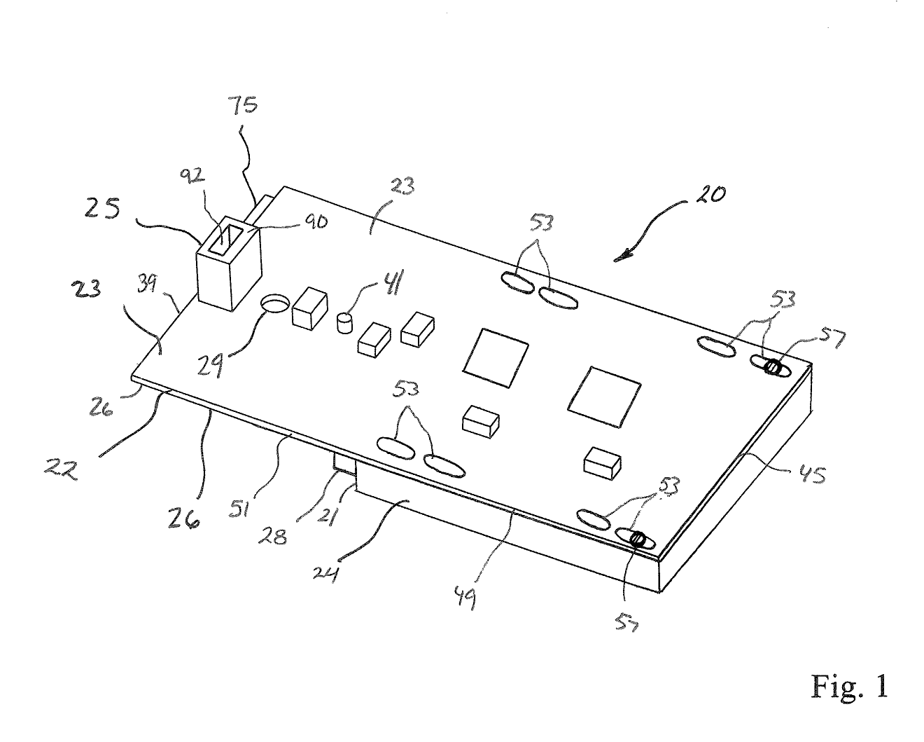

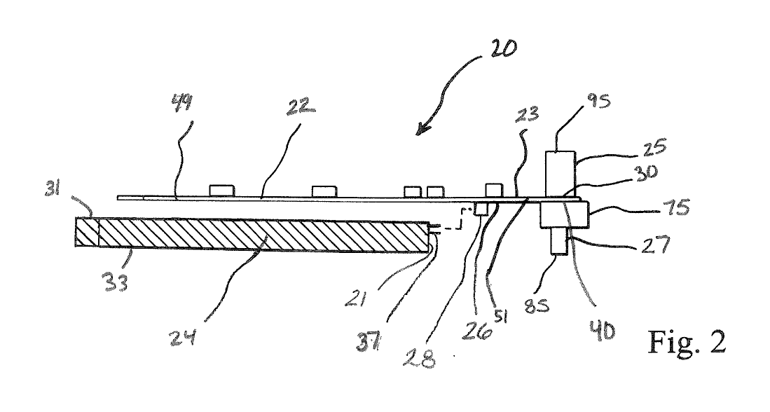

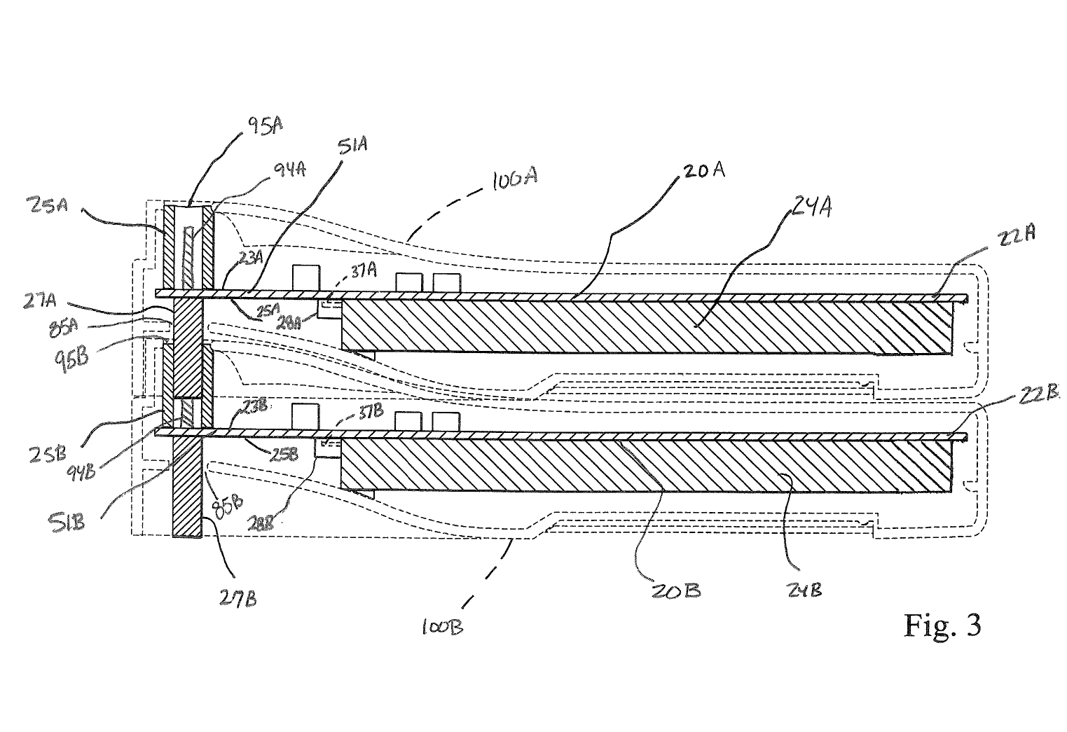

Referring now to FIGS. 1-2, an interface connector, generally designated 20, includes a circuit board overlay 22 which may be used as a standalone interface connector or in conjunction with a hardware device, such as that exemplified by a hard disk drive body 24 to form an operational hardware unit connectable to a primary digital processing or data generating device. Such circuit board overlay 22 includes a first side 23 supporting a first male connector 25 and an opposing second side 26 supporting a second female connector 27. A hardware connector 28 is also mounted to the circuit board overlay 22 for connecting the drive body 24 to the circuit board overlay 22. Such first and second connectors 25 and 27 are aligned in a parallel relationship with outwardly facing connector openings 85 and 95 to facilitate stacking of multiple hardware units together in series and provide the versatility to be used internally inside a computer casing, in a tower configuration, or externally with a housing such as those exemplified by phantom lines in FIG. 3 as a peripheral to be connected to a computer or other digital processing or generating device.

Referring now to FIGS. 1-2 and 5-6, the circuit board overlay 22 is a rectangular, planar, printed circuit board including a mounting section 49 and an adjacent interface connector extension 51. Both sections 49 and 51 cooperate to carry the necessary electrical components and tracings or conductive paths to transmit signals between the connectors 25 and 27 and the drive body 24 such that when the interface connector 20 is connected to a primary device, such drive body 24 may interface with such primary device via the circuit board overlay 22 circuitry and connectors 25 and 27. Such electrical compenentry includes such components as diodes, capacitors, integrated circuits, clocks, and capacitors and other electrical components to transmit signals between the connectors and the main drive body 24.

With reference to FIGS. 4-6, the mounting section 49 is about twice as long as the interface connector section 51 and is constructed to cover and be mounted to the top surface 31 of the main drive body 24. For connection to the drive body 24, the mounting section 49 includes a set of eight mounting slots 53 projecting through the overlay 22 and positioned near the lateral sides of the mounting section 49 such that when the mounting section is placed over the top surface 31 of the drive body 24, at least one mounting slot 53 on each side of the mounting section will align with a fastener hole 47 on the drive body 24. A pair of screws 57 threaded through the aligned slots 53 and into the corresponding fastener holes 47 fastens the mounting section 49 to the drive body 24.

With continued reference to FIG. 5, the first or top side 23 of the circuit board overlay 22 includes a male connector contact area 30 directly on the surface of the circuit board overlay 22. The male connector contact area 30 is positioned centrally between the long sides of the circuit board overlay and near the rear most edge 39 in the interface connector section 51. The male connector contact area 30 includes six contacts 61 and solder rings 63 configured to connect to the contact lead end of a male 1394 compatible connector projecting outwardly at a right angle from the overlay 22. An intermediate light emitting diode (LED) 41 is incorporated to facilitate receipt of infrared signals to transmit signals between a remote device and the drive body 24. A forward LED 43 is positioned along the forward edge of the circuit board overlay 22 and may be used for a similar function. Alternatively, either LED 41 or 43 may be used to indicate operational status of the drive body 24.

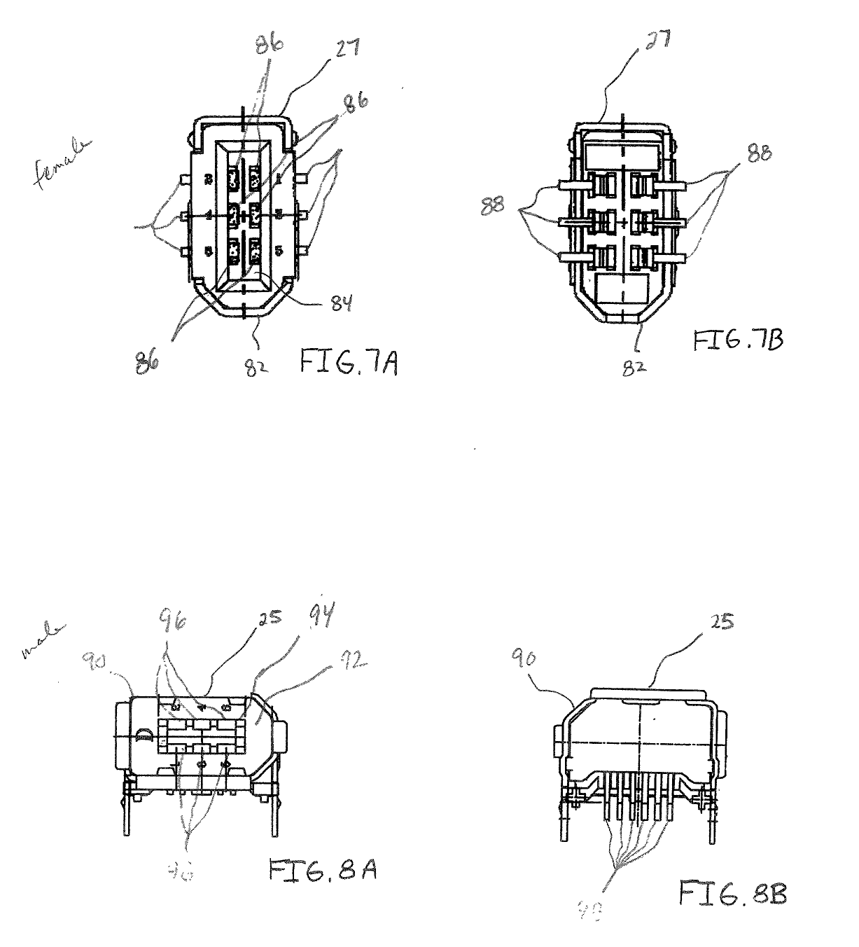

Referring now to FIG. 6, the second side 26 of the circuit board overlay 22 includes a female connector contact area 40 positioned directly beneath the male connector contact area 30 on the first side 23. Such female connector contact area 40 includes a set of solder rings 65 and a set of six contacts 67, both of which form a contact area 40 configured to connect to the contact lead end of a female 1394 compatible connector projecting outwardly at a right angle from the overlay 22. Adding increased versatility to the circuit board overlay 22 is a second male connector contact area 69 having six contact points 71 and solder points 73 arranged to accommodate a rearwardly projecting male 1394 connector 75 (FIG. 10). Further included on the second side 26 is a forty-four pin connector 28 for electrically connecting the hard drive body 24 to the circuit board overlay 22. The openings of the forty-four pin connector lie in a plane parallel to the second side 26 of the overlay 22 and are dimensioned to receive the connector pins 37 of the drive body 24. Advantageously, this removes the necessity of modifying the drive body 24. A power source connector 77 (FIG. 9) is also provided and mounted to the bottom surface 33 of the overlay 22. Such power source connector 77 includes a receptacle 79 and a central conductive post 80 for receiving a complementary connector from a power supply such as that conventionally used to power external computer peripherals.

An anchoring aperture 29 extends through the interface connector extension 51 and may be used to receive an insert or anchor (not shown) for securing the hard drive unit within a casing or other mounting structure.

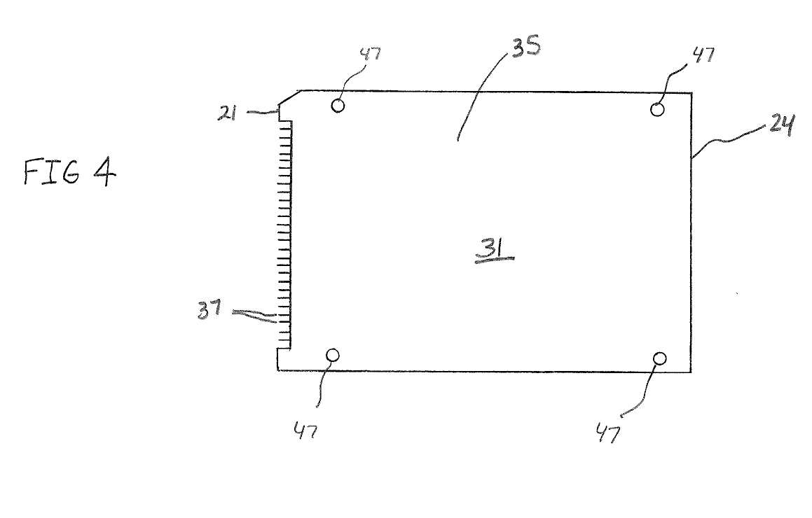

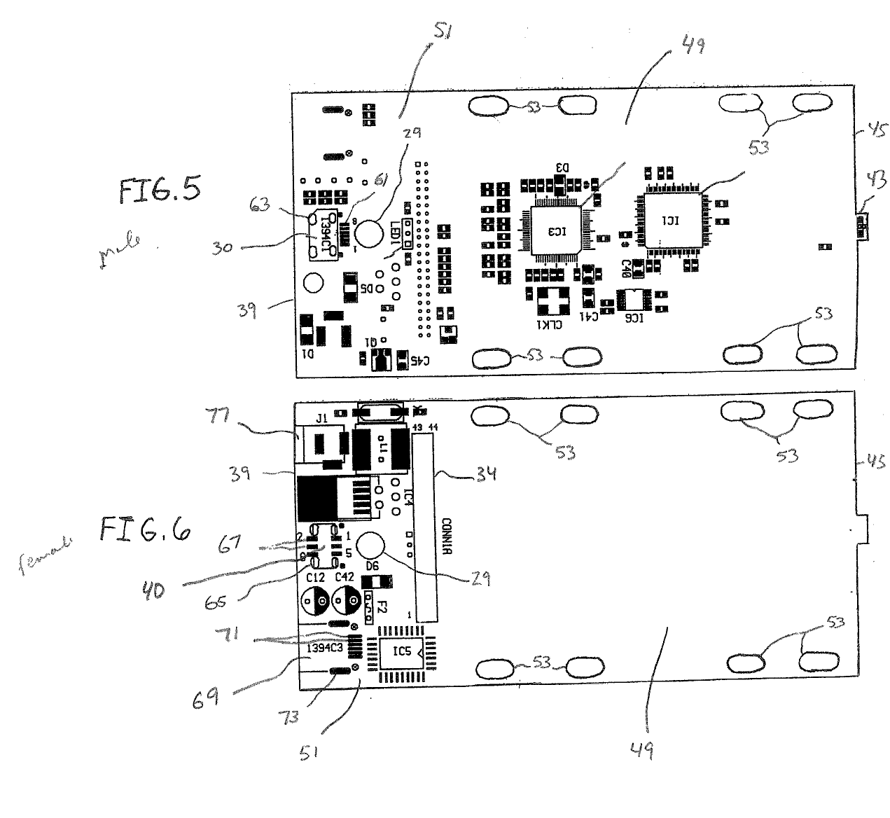

Connected to the overlay 22 in the interface connecting section 51 are the first and second connectors 25 and 27. Such connectors 25 and 27 and their respective locations on the overlay 22 are shown in simple block representations in FIGS. 1-3, and 9-10. Referring now to FIGS. 7A, 7B, 8A, and 8B, the more detailed illustrations will now be described. For exemplary purposes, both connectors 25 and 27 are IEEE 1394 compatible. The 1394 connector has been found to extremely suitable for a variety of digital applications and is rapidly becoming a standard in the computer industry. Its high speed capabilities facilitate the transfer of large amounts of digital data. It will be appreciated however, that the use of a 1394 connector is merely for purposes of illustration and is not meant to be limiting.

Referring now to FIGS. 1-2, 7A, 7B, and 9, the female six pin 1394 connector 27 includes a generally rectangular housing 82 with one narrow end having a pair of faceted sides. When viewed from the top side (FIG. 7A), the female connector includes a central rectangular receptacle 84 including six marginally disposed spaced apart contacts 86. When viewed from the bottom side (FIG. 7B), the female 1394 connector includes six leads 88 to be soldered onto their six counterpart contacts 67 in the female connector contact area 40 such that the open end is furthest away from the overlay 22. The housing 82 is soldered onto the solder rings to secure the female connector 27 to the overlay 22.

Referring now to FIGS. 1-2, 8A, 8B, and 9, the male 1394 connector 25 includes a generally rectangular housing 90 with one narrow end having a pair of faceted sides. The housing 90 is constructed to be telescopically received over a female 1394 connector in a close fitting relationship. When viewed from the top side (FIG. 8A), the male connector includes a central contact well 92 in the shape of the housing and including a central plug 94 with six marginally disposed spaced apart contacts 96. When viewed from the bottom side (FIG. 8B), the male 1394 connector includes six leads 98 along one side to be soldered onto the six counterpart contacts 61 in the male connector contact area 30. The housing 90 is soldered onto the solder rings 63 to secure the housing to the overlay 22. It will be appreciated that the six leads 98 may need to be bent at an angle to accommodate the right angle connector 27 connection to the overlay 22.

Referring now to FIGS. 2 and 9, both connectors 25 and 27 are arranged in a linear relationship with both free ends facing outwardly in a plane parallel to the overlay 22. In other words, the male and female 1394 connectors 25 and 27 project at right angles from the overlay and include outwardly facing contact openings 95 and 85 respectively. This arrangement facilitates the stacking of multiple interface connectors 20 and their respective drive bodies 24 as will be discussed below. While an offset arrangement may also be considered it is preferable to linearly align the connectors 25 and 27. The male and female contact areas 30 and 40 include passthrough connections (not shown) such that the drive body 24 may be inoperational and signals may still be passed between the female connector 27 and the male connector 25. Thus the interface connector 20 may act as a standalone interface connector and does not require the hardware unit 24 to be operational or even connected. If the hardware unit 24 is attached, signals are directed to the hard drive unit 24 as directed by a processing device connected to one of the connectors.

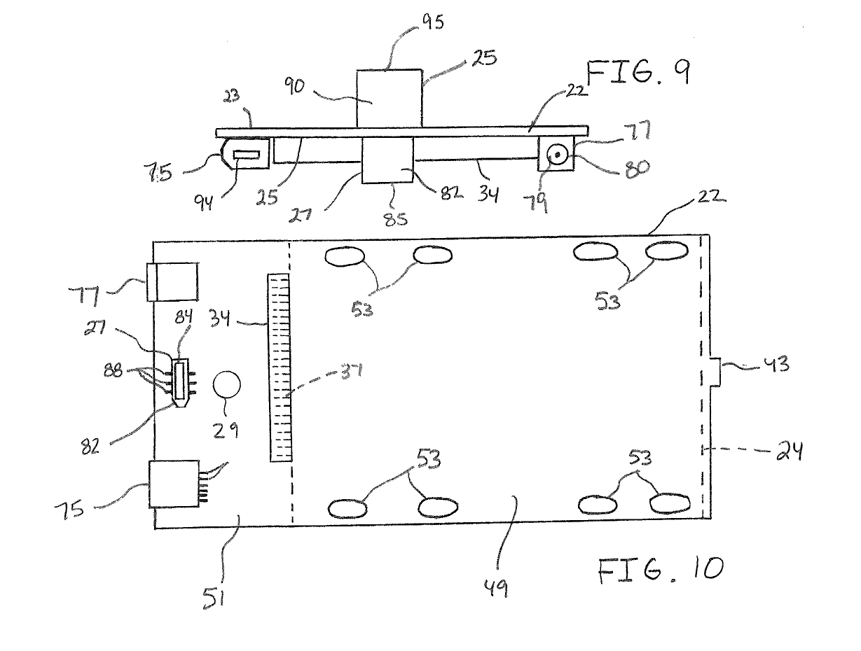

Referring now to FIG. 11, a surface mount configuration in a linearly aligned male and female connector 25 and 27 arrangement requires that the surface contact areas 30 and 40 are arranged so as to not interfere with one another. FIG. 11 illustrates the respective surface contact areas as if the circuit board overlay 22 were transparent and illustrates the respective contact areas 30 and 40 solder ring and contact patterns avoiding such interference. The left hand leaning cross hatching figures represent the male contact area 30 and its respective solder rings 63 and contacts 61. The right hand leaning cross hatching figures represents the female contact area 40 and its respective solder rings 65 and contacts 67. The respective contacts 61 and 67 do not interfere or short one another in this linear connector arrangement which facilitates the stacking configuration of multiple units.

The second male connector 75 is constructed similarly to the primary male connector 25 as illustrated in FIGS. 8A and 8B and like designations are used for like components. One exception is that the contacts 98 on the second male connector are bent at a 90 degree angle to accommodate the rearwardly facing connection provided by the second male connector 75.

For exemplary purposes, the hardware device 24 is a hard disk drive body with a generally rectangularly shaped casing 35 having top and bottom planar surfaces 31 and 33 enclosing internal electrical and working components (FIGS. 2 and 4). A preferred drive body 24 is a hard disk drive unit, Model No. HDD2152, available from Toshiba Corporation in the form to of a 2.5 inch hard disk drive having a capacity of 10.0 GB for storing multimedia data such as digital imagery, audio files, movie files, as well as other magnetically storable data. The selection of a hard disk drive is for exemplary purposes and is not meant to be limiting. Thus, it will be appreciated that a variety of hardware devices may be connected to the circuit board overlay 22 for use in connection with a processing device or other digital device.

The main drive body 24 is detachable from the circuit board overlay 22 and includes all the necessary components for storing and retrieving data. The back end 21 of the main drive body 24 includes a set of forty-three interface connector pins 37 to connect to the hardware connector 28 on the circuit board overlay 22. In this exemplary drive unit, the connector pins 37 project straight out in the rearward direction parallel to the top and bottom surfaces 31 and 33 of the casing 35. For purposes of illustration, the horizontal direction is defined as the plane in which the connector pins 37 project. The top surface 31 of detachable hard disk drive unit 24 includes a set of four threaded fastener holes 47 disposed near the corners of the drive body 24 for receipt of a threaded fastener 57 securing the circuit board overlay 22 to the drive body 24.

In use, the interface connector 20 may be used with or without an accompanying drive body 24. For purposes of illustration it will be assumed that a drive body 24 is to be incorporated. Referring now to FIG. 2, the user selects the drive body 24 with the desired characteristics to enhance a primary device. In this example, a hard disk drive 24 is selected to increase the storage capacity of a primary device by storing digital data. The connector pins 37 of the drive body 24 are aligned with the connector sockets in the 44 pin connector 28 and such that the top surface 31 of the drive body is abutting the second side 26 of the overlay 22 in the mounting section 49. The drive body 24 is then driven toward the rear edge 39 of the overlay 22 until the connector pins 37 are fully inserted into their respective sockets in the hardware connector 28. At this point, at least two opposing slots 53 on the overlay 22 will align with fastener holes 47 on the drive body 24. A threaded fastener 57 is inserted through each mounting slot aligned with a threaded fastener hole and threaded into the hole 47 until the hard drive body 24 is secured to the mounting section 49 of the overlay 22. At this point, the interface connector 20 and drive body 24 form a hardware device unit that may be used in conjunction with a primary device such as a desktop or laptop computer, network computer system, or a digital data generator such as a digital camcorder.

To connect the hardware device unit to a primary device (not shown), a conventional interface cable (not shown) having one end compatible with one of the connectors 25 or 27 which in this case is a 1394 interface cable. The interface cable is selected to engage the port or interface connector on the primary device and one of the connectors 25 or 27 on the interface connector 20. A power supply connector (not shown) is also plugged into the power receptacle 77 (FIG. 9) and the other end connected to a power source. When the power source is activated and the primary device is operational, communication between the drive body 24 and to the primary device via the connected connector 25 or 27 may take place. The circuitry on the overlay 22 places each of the connectors 25 and 27 in electrical communication with one another as well as the drive body 24 if it is connected to the hardware connector 28.

It will be appreciated that it is a simple process to remove the drive body 24 by unplugging the power source, unscrewing the fasteners 57, and withdrawing the drive body pins 37 from the hardware connector 28. A replacement drive body 24 may then be substituted as described above.

The advantage of the interface connector 20 of the present invention is even more apparent if connection of more than one hardware device 24 to a primary device is desired. Referring now to FIG. 3, a pair of interface connectors 20A and 20B of like configuration are illustrated within respective external peripheral casings as indicated by phantom lines 100A and 10B. An acceptable housing for the interface connector 20 may be found in co-pending U.S. Ser. No. ______, entitled Stackable Peripheral Housing, filed on Jan. 8, 2001 and is hereby incorporated by reference in its entirety. The casings includes access openings surrounding the outwardly facing connective openings 95 and 85 for each respective connector 25 and 27. The respective interface connectors 20A and 20B are aligned in a vertical relationship with the female connector 27A of the top interface connector 20A linearly aligned with the male connector 25B of the bottom interface connector 20B. The female connector 27A is then inserted into the male connector 25B until it firmly seats in place. At this point, a connector pairing is formed and signals may be passed between the female connector 27A and the male connector 25B. Both ends of the connector pairing, connectors 25A and 27B are open and may be connected as described above to a primary device. It will be appreciated that any number of interface connectors 20 may be connected in this manner and each may includes a similar or dissimilar drive body 24 or no drive body at all.

Alternatively, the vertically projecting connectors 25 and 27 may be used to connect adjacent interface connectors 20 while the rearwardly projecting connector 75 may be used to connect to the primary device. Since the rearwardly projecting connector 75 is also in electrical communication with the other connectors 25 and 27 as well as the hardware connector 28, signal flow between the drive body 24 and primary device may take this path as well. Individual external housings are not necessary and such interface connectors 20 could be rack mounted in a tower configuration or other primary device casing. A power source may be connected to the power source connector 77 as described above. In a stacked configuration, due to the connector pairings formed between adjacent interface connectors 20, only one connector cable is required to connect the stacked configuration to the primary device. In addition, only one power cable is required to one of the interface connectors to power all devices. Thus, it will be appreciated that the present invention allows for a multiple device stacked configuration which omits the use of interface cables except at one end of the stack which is the connector end that is connected to the primary device. The configuration may be also hot swappable.

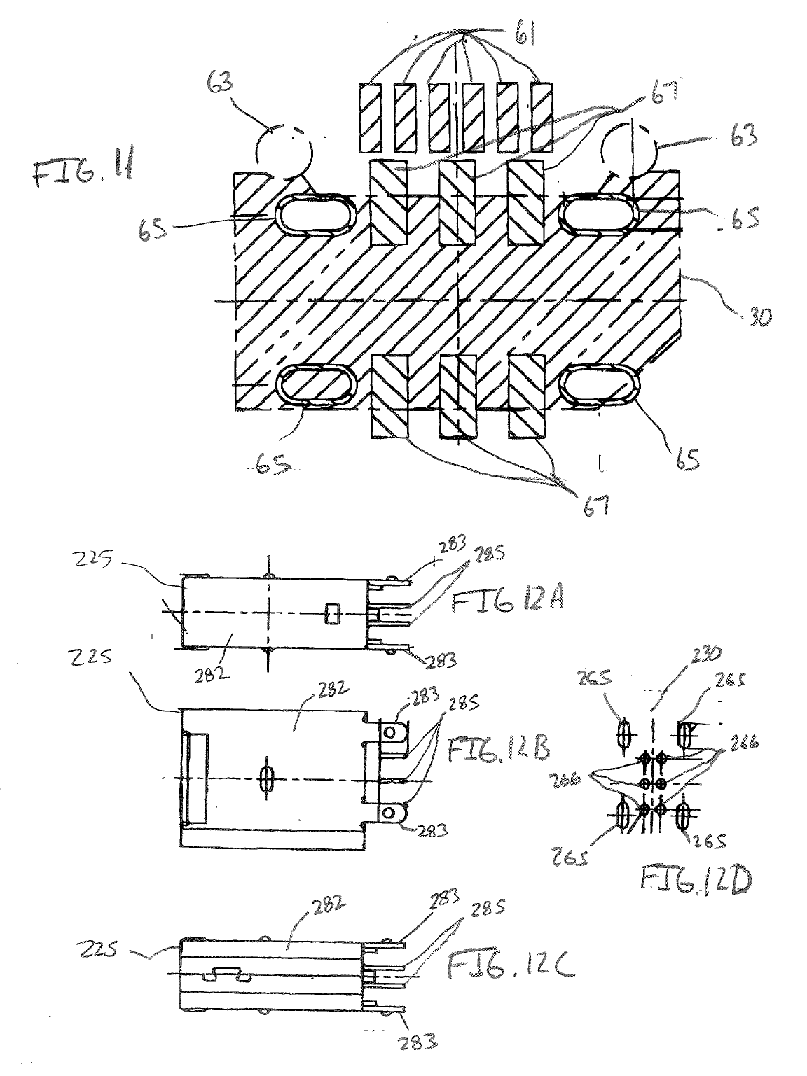

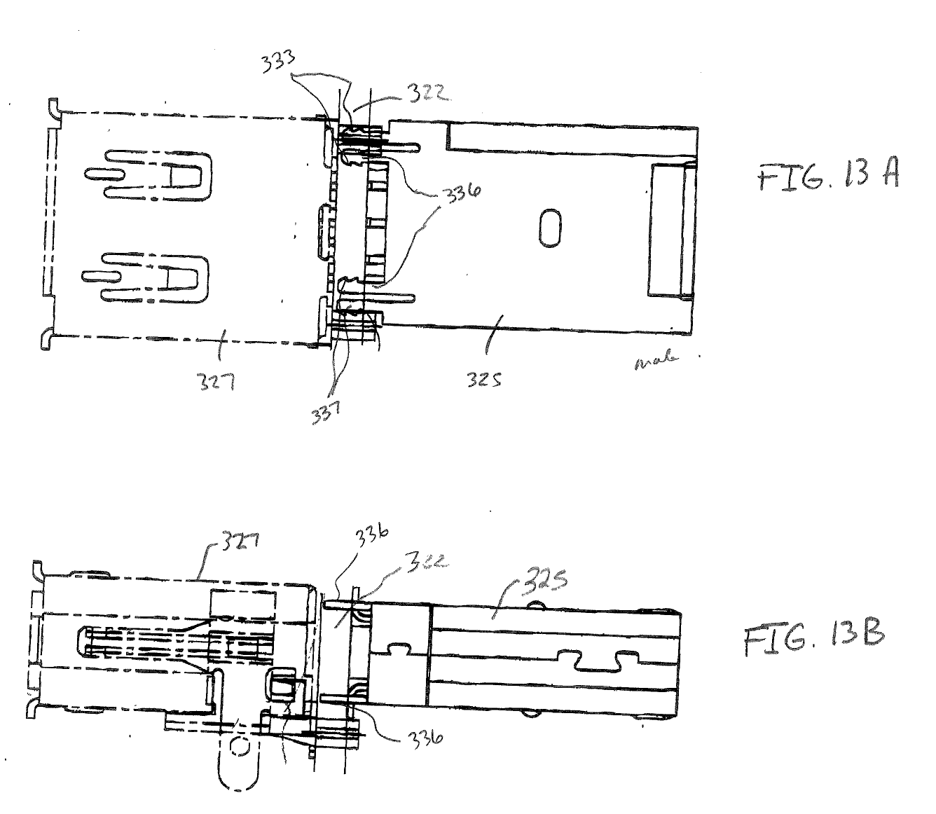

While a vertical stacking arrangement was described herein, it will be appreciated that the interface connector 20 could stacked in any orientation as long as the respective connectors 25 and 27 of adjacent units were aligned. In addition, in some situations, it may be desirable to only use one connector projecting at a right angle on either side of the circuit board overlay 22. This is desirable in a rack mount configuration wherein the interface connector may be slid into a rack mount and plugged into a complementary interface connector located in the rack mount housing. Due to the demand of frequent removal of the interface connectors, an alternative connector configuration having improved structural integrity may be used if desired. Referring now to FIGS. 12A-12C, a male 1394 connector 225 includes a housing 282 having a set of four board locks 283 near each corner of the housing and a set of six connector pins 285 in a two column by three row configuration is used for a more secure configuration than provided by the surface mount configuration described above. The connector pins 285 project in a plane parallel to the sides of the housing 282 and are meant to be inserted into the circuit board overlay 22. The male contact area 230 for this type of connector includes a set of four solder slots 265 and pin receiving sockets 266 spaced and dimensioned to receive the corresponding board locks 283 and six pin set 285 on the male connector 225. As the pins 285 and board locks 283 are inserted into the circuit board overlay 22 and the board locks may additionally be soldered into the circuit board, structural integrity of the connector 225 and circuit board overlay 22 connection is increased to resist separation from repeated disconnection of the interface connector 225 from another connector.

Referring now to FIGS. 13A and 13B, an alternative connector may be incorporated to enhance the structural integrity of the surface mount configuration. A pair of male and female connectors 325 and 327 are illustrated in a linearly aligned configuration with the circuit board overlay 322 sandwiched between them. The respective contact areas would be as illustrated in FIGS. 5, 6, and 11. An additional feature is incorporated to anchor the male connector 325 to the circuit board overlay which inhibits the connector from being inadvertently disconnected from the circuit board when the disconnected from another connector. A set of four board locks 336, one at each corner of the male connector 325 is used and inserted into locking slots in the circuit board. In addition, the board locks incorporate outwardly projecting teeth 337 to sink into the outer diameter of the locking slots. The teeth are angled to resist removal of the connector away from the circuit board. This increases the structural integrity of a surface mount configuration.

It will further be understood that the present invention is not limited to any particular platform such as the Macintosh, Windows, or UNIX systems. In addition, the interface panel may be constructed to accommodate any connector well known in the art and is not limited by the examples provided herein.

While several forms of the present invention have been illustrated and described, it will also be apparent that various modifications may be made without departing from the spirit and scope of the invention.

What is claimed is:

1. An interface connector for a hardware device comprising:
a circuit board overlay including an interface connector section, said interface connector section including opposing first and second sides;
a first electrically conductive contact area on said first side;
a second electrically conductive contact area on said second side in electrical communication with said first electrically conductive contact area;
a first connector in electrical communication with said first contact area and projecting outwardly from said first side; and
a second connector in electrical communication with said second contact area projecting outwardly from said second side in a plane substantially parallel to a plane defined by the outward projection of said first connector.

2. An interface connector as set forth in claim 1 wherein:
said second connector is complementally constructed to said first connector.

3. An interface connector as set forth in claim 1 wherein:
at least one of said first and second connectors is constructed to releasably engage the other of said first and second connectors on an adjacently stacked interface connector of a like configuration.

4. An interface connector as set forth in claim 1 wherein:
said first and second connectors project at right angles from said interface connector section and are arranged in a substantially linear alignment.

5. An interface connector as set forth in claim 1 further including:
a third connector on one of said sides constructed to releasably engage a hardware device and being in electrical communication with said first and second contact areas.

6. An interface connector as set forth in claim 1 wherein:
said first and second connectors are IEEE 1394 compatible connectors.

7. An interface connector as set forth in claim 1 wherein:
said first connector is a female six socket 1394 connector; and
said second connector is a male six pin 1394 connector.

8. An interface connector as set forth in claim 1 further including:
a fourth connector mounted on one said sides and in electrical communication with said third connector, said fourth connector being configured like one of said first and second connectors and projecting in a plane parallel to said circuit board overlay.

9. An interface connector as set forth in claim 1 wherein:
said first and second connectors include signal and power wires.

10. An interface connector as set forth in claim 5 wherein:
said third connector is connected to a hard disk drive.

11. An interface connector as set forth in claim 1 wherein:
said circuit board overlay includes an anchoring aperture for securing said overlay to a casing having an anchor passing through said aperture.

12. An interface connector as set forth in claim 1 wherein:
at least one of said connectors includes a board lock with teeth for insertion into said circuit board overlay.

13. An interface connector as set forth in claim 1 wherein:
at least one of said connectors include a set of connector pins and board locks for insertion into said circuit board overlay.

14. A multi-unit computer hardware apparatus comprising:
a plurality of hardware units, each of said hardware units including a circuit board extension having a top side and bottom side, each of said units further including:
a first contact area in electrical communication with said top side;
a second contact area in electrical communication with said bottom side;
a first connector in electrical communication with said first contact area;
a second connector in electrical communication with said second contact area and complementary to said first connector; and
whereby said units may be placed in a stacked arrangement and adjacent first and second connectors releasably engaged leaving an open connector at one end of said stacked arrangement for connection to a connection port on said computer.

15. A hardware device for connecting to a computer comprising:
a hard drive unit;
a planar printed circuit board having opposing sides and electrically connected to said hard drive unit;
a male six pin 1394 connector electrically connected to said circuit board on a first side of said printed circuit board and projecting at a substantially right angle to said circuit board and having a connective end disposed distally from said circuit board;
a female 1394 receptacle connector electrically connected to said circuit board on an opposing side and projecting in a plane parallel to a plane defined by the projection of said male connector and having a connective end disposed distally from said circuit board; and
whereby a second hardware device may be placed in a stacking relationship with said hardware device to align adjacent male and female connectors for releasable engagement with one another.

16. A hardware device configured to be connected to a computer comprising:
a hardware unit having a first side with a first electrically conductive contact area and an opposing second side having a second electrically conductive contact area, said contact areas being in electrical communication with one another and said hardware unit;
a first connector in electrical communication with said first contact area and projecting outwardly from said first side;
a second connector in electrical communication with said second contact area projecting outwardly from said second side and substantially linearly aligned with said first connector, said second connector being constructed to releasably engage a first connector on an adjacently stacked hardware unit; and
whereby one of said connectors may be connected to a computer.

17. A method of stacking and connecting a plurality of hard drives comprising the steps of:
providing a hard drive unit having a printed circuit board with a first outwardly projecting connector and a second connector configured to connect to a computer;
providing another hard drive unit having a printed circuit board including a complementary connector projecting outwardly from said circuit board and configured to releasably engage said first connector;
stacking said drive units to arrange said first and second connectors in a substantially vertically aligned relationship;
connecting said first and complementary connectors directly to one another to form a vertically aligned connector pair; and
whereby said second connector may be connected to a computer such that all connected hard drive units may receive signals and power from said computer upon its operation.
